(19) United States
(12) Patent Application Publication
(10) Pub. No.: US 2011/0148683 A1
(43) Pub. Date: Jun. 23, 2011

(54) ANALOG-TO-DIGITAL CONVERTER

(75) Inventor: Duncan Bremner, Renfrewshire (GB)

(73) Assignee: ITI Scottland Limited, Glasgow (GB)

(21) Appl. No.: 12/678,128

(22) PCT Filed: Sep. 15, 2008
(86) PCT No.: PCT/GB08/03111

§ 371 Date: Jan. 19, 2011

(30) Foreign Application Priority Data
Sep. 13, 2007 (GB) 0717894.0

(51) Int. Cl. H03M 1/12

(52) U.S. Cl. 341/158

(57) ABSTRACT

There is provided an analog-to-digital converter that comprises an analog signal input for receiving an analog signal; a reference voltage input for receiving a reference voltage signal; and a plurality of comparators, one input of each comparator being connected to the analog signal input, and the other input of each comparator being connected so as to receive a respective portion of the reference voltage signal; wherein at least one of the plurality of comparators can be selectively activated and deactivated in order to determine a mode of operation of the analog-to-digital converter.

### TECHNICAL FIELD OF THE INVENTION

The invention relates to an analog-to-digital converter (ADC), and in particular relates to an analog-to-digital converter in which the power consumption is optimised.

### BACKGROUND TO THE INVENTION

Analog-to-digital converters (ADCs) are well known, and convert continuous analog signals into discrete digital signals. Most ADCs consist of two basic functions, an input signal sampling circuit, and a conversion circuit which converts the sampled input into a defined number of digital levels (i.e. a 6-bit converter would be capable of discriminating between 64 discrete levels). Conventional types of ADCs convert an analog signal into a digital signal according to a predefined conversion transfer function or law. This law could be logarithmic, exponential, or linear with a given bit length. Well-known examples of non-linear converters are the A-law/p-law PCM Codecs in the telecom industry. Although these ADCs are optimised for power consumption, this power consumption cannot normally be adjusted to use different laws. For example, a converter which has been designed as a 6-bit linear converter cannot normally be modified to implement a logarithmic law as the majority of the internal circuit components must remain powered up. It is also well known that ADC power can be decreased by reducing the sample rate or by reducing the number of bits which are resolved, although this latter technique normally only reduces the power by a relatively small amount if the ADC has been implemented using most of the common and well known techniques. However these approaches are not ideal for implementing very fast converters.

An alternative type of ADC, known as a flash converter, is more suitable for very high speed applications and consists of many parallel level comparator blocks which sequentially indicate ‘high’ as the input voltage exceeds their reference voltage. This converter consists of a number of converters, approximately equal to the number of levels followed by a post-processing digital block to convert the comparators parallel output signals into a standard binary representation. This approach to conversion is much quicker than the more conventional pipelined converter but consumes a significant amount of power.

A conventional flash analog-to-digital converter 2 is shown in FIG. 1 which converts an analog signal into a 2-bit binary signal. The converter 2 has an input 4 for receiving an analog signal, Vᵢₙ, and a reference voltage input 6 for receiving a reference voltage, V_{ref}, the input 6 being connected to four resistors 8 arranged in series. Three comparators 10 are provided (individually labelled S1, S2 and S3), that are powered by a voltage supply V₊, and whose non-inverting inputs are connected to the analog signal Vᵢₙ. The inverting input of each comparator 10 is connected to a point between a respective pair of the resistors 8. Thus, the resistors 8 act as a voltage divider for each of the comparators 10, so that the inverting inputs of the comparators receive a voltage of V_{ref}/4, 2V_{ref}/4 and 3V_{ref}/4 respectively. The outputs of the comparators 10 (labelled D1, D2, D3 respectively) are provided to a digital conversion block 12 which converts the received comparator outputs to a 2-bit binary signal (B0, B1). Although the diagram shows a 4-level, 2-bit converter for simplicity, the methodology is equally applicable for larger converters.

Each comparator 10 produces a “1” when the analog signal Vᵢₙ is higher than the respective portion of the reference voltage V_{ref} applied to its inverting input, and a “0” otherwise. So, if the analog input Vᵢₙ is between 2V_{ref}/4 and 3V_{ref}/4, comparators S1 and S2 produce “1”s (i.e. D1 and D2 are 1), and comparator S3 produces a “0” (i.e. D3 is 0). The comparator where the outputs change from ones to zeros is the point where the analog signal becomes smaller than the respective comparator reference voltage level. This type of conversion is known as “thermometer encoding”. The thermometer code is converted into the appropriate binary output code by the conversion block 12.

This type of ADC 2 has excellent high-speed performance, as it compares the analog input voltage Vᵢₙ against all of the reference voltage levels simultaneously. Therefore, the time required to perform the measurement is equal to the time taken for a single comparator to change state.

However, as described above, although this type of analog-to-digital converter has reasonable power consumption, it is not possible to provide for the selection of the conversion transfer function or law.

Therefore, it is an object of the invention to provide an analog-to-digital converter that provides flexibility in the law selected for the conversion and which has improved power consumption.

### SUMMARY OF THE INVENTION

There is provided an analog-to-digital converter that comprises an analog signal input for receiving an analog signal; a reference voltage input for receiving a reference voltage signal; and a plurality of comparators, one input of each comparator being connected to the analog signal input, and the other input of each comparator being connected so as to receive a respective portion of the reference voltage signal; wherein at least one of the plurality of comparators can be selectively activated and deactivated in order to determine a mode of operation of the analog-to-digital converter.

According to a second aspect of the invention, there is provided a portable device, comprising an analog-to-digital converter as described above.

### BRIEF DESCRIPTION OF THE DRAWINGS

The invention will now be described, by way of example only, with reference to the following drawings, in which:

FIG. 1 is a block diagram of a known analog-to-digital converter;

FIG. 2 is a block diagram of an analog-to-digital converter in accordance with an aspect of the invention;

FIG. 3 is a graph showing the comparative power gains for different laws when using an ADC in accordance with the invention; and

FIG. 4 is a table showing the power consumption for different comparator configurations.

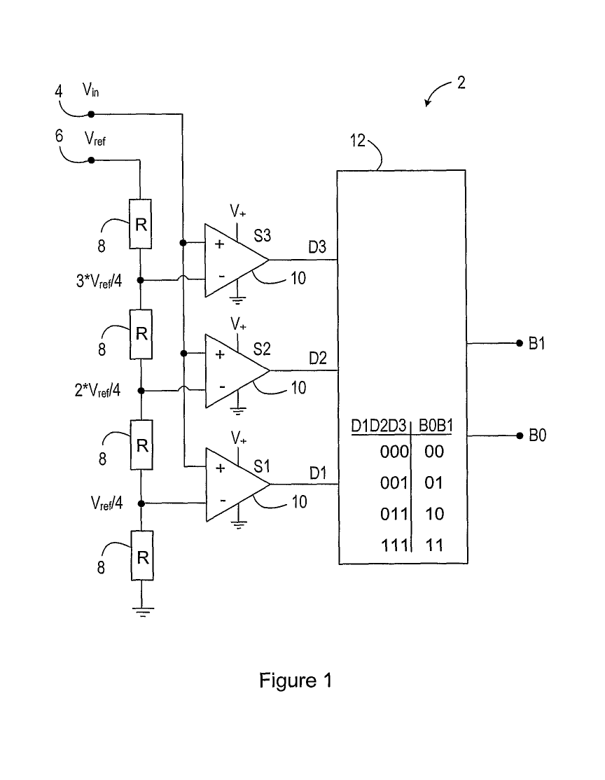

### DETAILED DESCRIPTION OF THE PREFERRED EMBODIMENTS

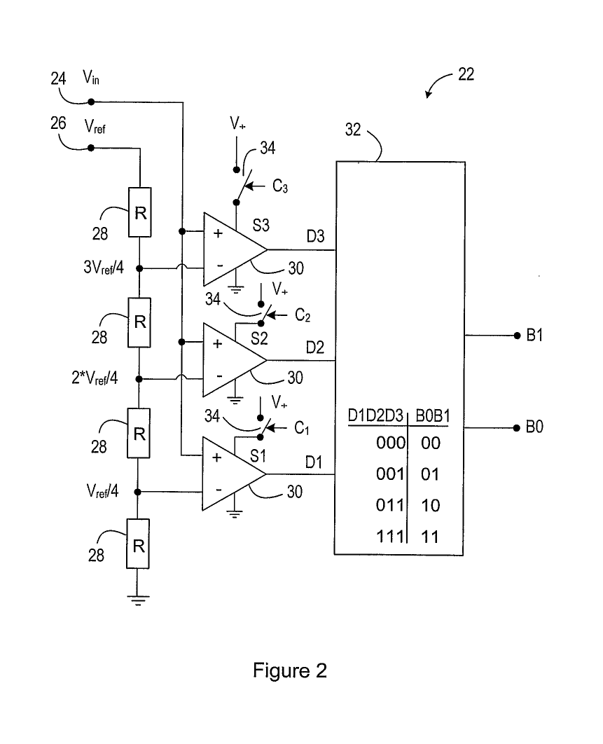

FIG. 2 shows an exemplary analog-to-digital converter (ADC) in accordance with an aspect of the invention. This analog-to-digital converter 22 converts an analog signal into a 2-bit binary signal. The converter 22 has an input 24 for receiving an analog signal, Vᵢₙ, and a reference voltage input 26 for receiving a reference voltage, V_{ref}, the input 26 being connected to four resistors 28 arranged in series. Three comparators 30 are provided (individually labelled S1, S2 and S3) that are powered by a voltage supply V₊, and whose non-inverting inputs are connected to the analog signal Vᵢₙ. The inverting input of each comparator 30 is connected to a point between a respective pair of the resistors 28. Thus, the resistors 28 act as a voltage divider for each of the comparators 30, so that the inverting inputs of the comparators receive a voltage of V_{ref}/4, 2V_{ref}/4 and 3V_{ref}/4 respectively. The outputs of the comparators 30 (labelled D1, D2 and D3 respectively) are provided to a conversion block 32 which converts the received outputs to a 2-bit binary signal (B0, B1).

As described above, each comparator 30 produces a “1” when the analog signal Vᵢₙ is higher than the respective portion of the reference voltage V_{ref} applied to its inverting input, and a “0” otherwise. So, if the analog input Vᵢₙ is between 2V_{ref}/4 and 3V_{ref}/4, comparators S1 and S2 produce “1”s (i.e. D1 and D2 are 1), and comparator S3 produces a “0” (i.e. D3 is a 0). The comparator where the outputs change from ones to zeros is the point where the analog signal becomes smaller than the respective comparator reference voltage level. This thermometer code is converted into the appropriate binary output code by the conversion block 32.

In accordance with an aspect of the invention, at least one of the comparators 30 is switched such that it can be selectively activated and deactivated in order to select the mode of operation of the ADC 22. In this illustrated embodiment, each of the comparators 30 is switched such that each comparator 30 can be selectively activated and deactivated independently of, or together with, the other comparators 30. However, it will be appreciated that in other embodiments, only one or some of the comparators 30 can be selectively activated and deactivated. It will be appreciated that there are several different methods of de-activation of circuits and the implementation shown in FIG. 2 does not preclude other implementations from being adopted.

In this illustrated embodiment, the comparator or comparators 30 are selectively activated and deactivated using a respective switch 34 positioned between the comparator 30 and its voltage supply V₊, with each switch 34 being controlled by a respective control signal C₁, C₂ and C₃.

By selectively activating and deactivating the comparators 30, the ADC 22 can implement different measurement sensitivities (i.e. number of bits in the output), and conversion transfer functions (for example logarithmic). The sensitivity of the ADC 22 can be varied with a direct impact on the power consumption. This permits, for example, optimisation of power consumption while in a monitoring mode or where the signal quality is particularly good; hence requiring less bits. Furthermore, complex detection mechanisms can be realised using this ADC 22.

Although a switch 34 is preferred in accordance with the invention, it will be appreciated by a person skilled in the art that any other suitable type of component can be used to selectively activate and deactivate the comparators 30.

In addition, although the ADC 22 is shown as having three comparators 30, it will be appreciated that any number of comparators 30 can be used as required for the ADC 22. For example, if the desired output is a 7-bit binary signal representing 64 possible input signal levels, the ADC will require 63 comparators. It will be appreciated that the power savings for a greater number of comparators is higher than the simple 2-bit example shown.

The component that generates the control signals for the switches 34 is not shown in FIG. 2.

If the power supply to one or more of the comparators 30 is switched as illustrated in FIG. 2, it is possible to reduce the power consumption of the ADC 22, depending on the application to which the ADC 22 is put. In one instance, for example a “sleep” mode, the least significant comparator (S1) can be kept active to monitor for any signal at the analog signal input 24, and all other converters 30 can be deactivated. In the example of FIG. 2, this would correspond to a 66% reduction in power consumed by the comparators 30 (one comparator is active while two comparators are inactive).

Furthermore, it is possible to reduce the resolution of the ADC 22 from 2 bits to 1 bit by only activating the second comparator (S2) and switching all others off; which again saves power. If this is extended to a more complex converter, say 6- or 7-bit (32 or 64 comparators), it is possible to dynamically change the sensitivity of the converter 22, or to set a detection ‘window’ with full resolution, while only consuming a fraction of the power by pre-selecting the appropriate comparators 30 according to a predefined algorithm. Additionally, these ‘windows’ could be set around the input signal transition points providing a greater degree of discrimination at these points.

Another advantage is that non-linear laws can be implemented (for example a simple log(2) law) by selective activation of comparators 30 which are chosen to a give a logarithmic signal detection law.

In each of these cases, the absolute or maximum resolution of the ADC 22 remains constant, but it will be appreciated by a person skilled in the art that this can be varied. However, the performance and power of the converter 22 is optimised to always conserve power (or otherwise) by reducing the total number of active comparators 30 in the ADC 22.

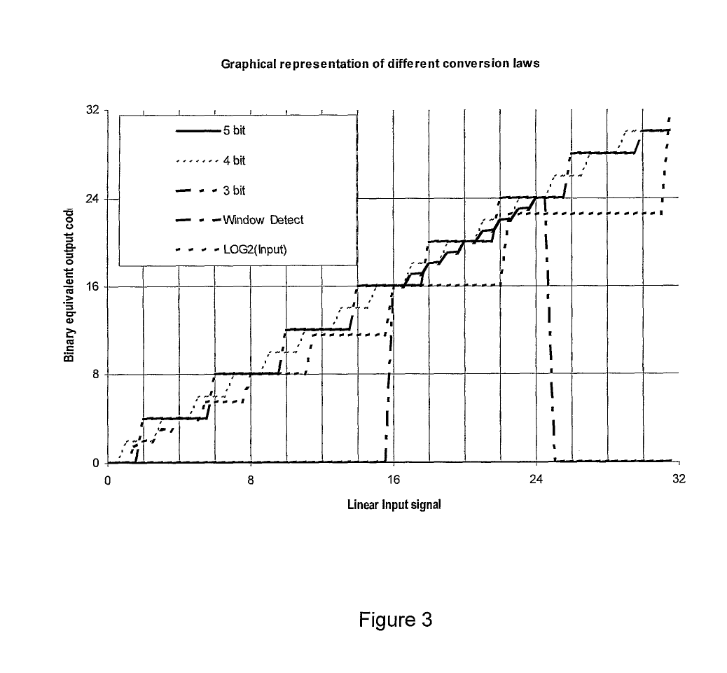

An example of some of the conversion transfer functions that can be implemented with an ADC 22 in accordance with the invention are shown by the graph in FIG. 3. The graph shows the digital binary output signal versus a linear input signal according to 5 different laws selected. In order to resolve the different laws on the graph, the conversion has been limited to 32 states (5 bit) but this can be expanded to any other level of discrimination by expansion, as will be appreciated by a person skilled in the art. The graph shows different conversion laws: 5-bit linear, 4-bit linear, 3-bit linear, a window detector with 5-bit accuracy in the window, and a 4-bit logarithmic conversion law. These laws are only examples of what can be implemented using the invention and a combination of these may be selected by those skilled in the art. A unique feature of this invention is that the converter may be dynamically modified to further save power. An example of this could be a ‘tracking window detector’ where the ‘window’ region is adjusted using digital control to enhance the sensitivity in the signal region.

The power savings in the converter 22 is directly proportional to the number of comparators 30 that are active, and so in the case of a 7-bit (64 level) ADC, a 7-bit linear converter would represent 100% power consumption (since all comparators are powered up), while a single level threshold detector (i.e. a single comparator) would only require around 1.5%; a 7-bit window detector operating over 25% of the total range would use 25% of the power; and a 5-bit full range detector would similarly use 25% of the power, as it is possible to turn off 75% of the comparators.

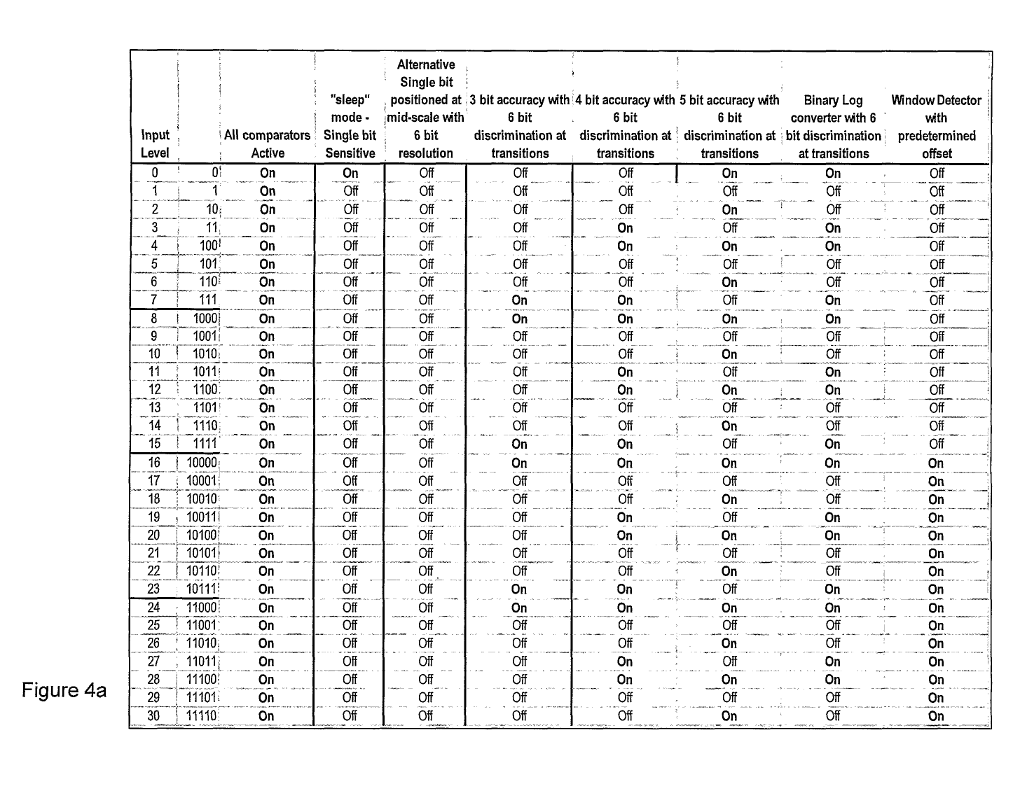

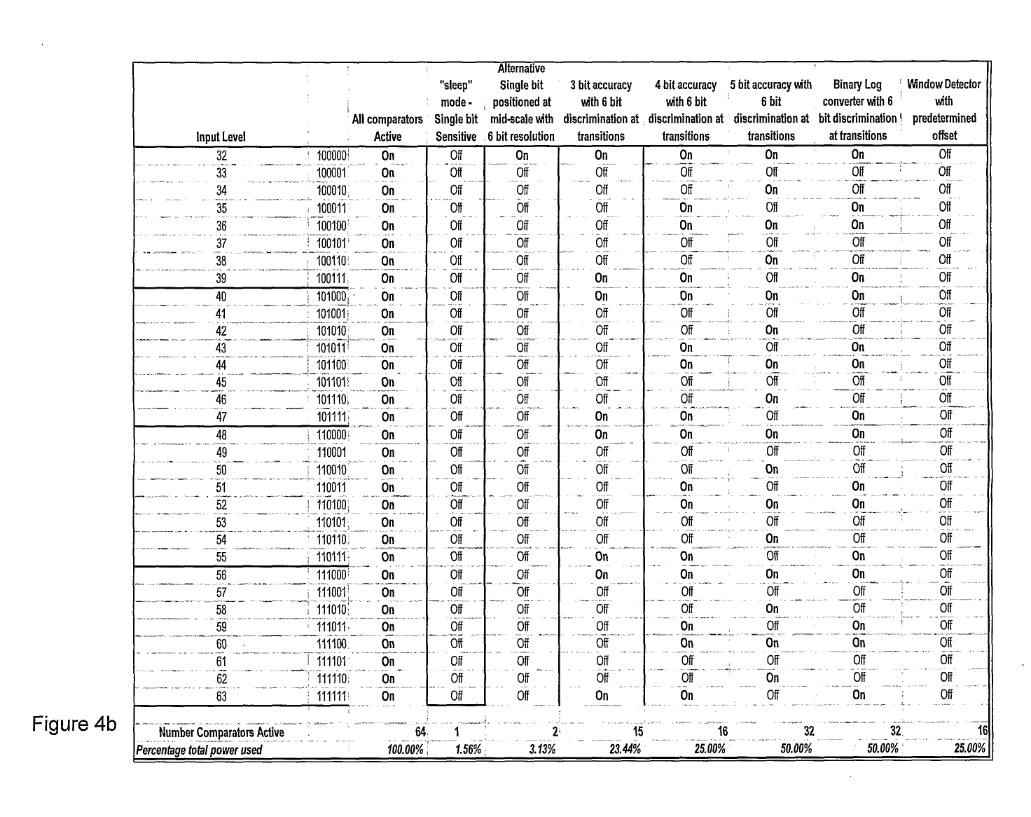

FIG. 4 is a table that illustrates the power consumption and the active comparators 30 in an ADC with 64 comparators 30 for different laws. The first column lists the input levels, which correspond to the comparators 30, the second column indicates the binary value, and the remaining columns indicate which of the comparators 30 are active for that particular law. At the base of the table, the number of active comparators is indicated, along with the relative power consumption for each law compared with a reference 7-bit converter where all the comparators are active.

The key technical advantage of the invention is that it allows the power consumption of a very high speed converter to be optimised while maintaining full functionality, if required. Complex and non-linear (even dynamically changing) conversion laws can be implemented. Thus the ADC is particularly suitable for battery-powered devices.

Thus the invention described above reduces the power consumption in approximately direct proportion to the number of digital levels being discriminated and can be modified dynamically under programme control.

1. An analog-to-digital converter, comprising:
an analog signal input for receiving an analog signal;
a reference voltage input for receiving a reference voltage signal; and
a plurality of comparators, one input of each comparator being connected to the analog signal input, and the other input of each comparator being connected so as to receive a respective portion of the reference voltage signal;
wherein at least one of the plurality of comparators can be selectively activated and deactivated in order to determine a mode of operation of the analog-to-digital converter.

2. An analog-to-digital converter as claimed in claim 1, wherein more than one of the plurality of comparators can be selectively activated and deactivated.

3. An analog-to-digital converter as claimed in claim 2, wherein each of the plurality of comparators can be selectively activated and deactivated.

4. An analog-to-digital converter as claimed in claim 2, wherein the comparators that can be activated and deactivated can be activated and deactivated independently of each other.

5. An analog-to-digital converter as claimed in claim 1, wherein a switch is provided between a comparator and its voltage supply, the switch being controlled to selectively activate and deactivate the comparator.

6. An analog-to-digital converter as claimed in claim 5, wherein the, or each, switch is controlled by a respective control signal.

7. An analog-to-digital converter as claimed in claim 1, further comprising a conversion block for converting the output of the comparators into a binary code.

8. An analog-to-digital converter as claimed in claim 1, wherein the output of the comparators is a thermometer code.

9. An analog-to-digital converter as claimed in claim 1, wherein the at least one comparator is selectively activated and deactivated in order to change an effective quantisation of the converter.

10. An analog-to-digital converter as claimed in claim 1, wherein the at least one comparator is selectively activated and deactivated in order to switch the converter between a sleep mode in which a single comparator is activated, and an operational mode in which a plurality of comparators are activated.

11. An analog-to-digital converter as claimed in claim 1, wherein the input of each comparator connected to the analog signal input is the non-inverting input of each comparator.

12. An analog-to-digital converter as claimed in claim 1, wherein the input of each comparator connected to receive the respective portion of the reference voltage is the inverting input of each comparator.

13. An analog-to-digital converter as claimed in claim 1, wherein the respective portion of the reference voltage signal is provided to each comparator by a voltage divider circuit.

14. A portable device, comprising an analog-to-digital converter as claimed in claim 1.
